(19) United States
(12) Patent Application Publication
(10) Pub. No.: US 2005/0022741 A1
(43) Pub. Date: Feb. 3, 2005

(54) Chemical vapor deposition apparatus and method of forming thin layer using same

(76) Inventors: Jung-Hun Seo, Gyeonggi-do (KR); Young-Wook Park, Gyeonggi-do (KR); Jae-Jong Han, Seoul (KR)

Correspondence Address: MARGER JOHNSON & McCOLLOM, P.C., 1030 S.W. Morrison Street, Portland, OR, 97205, US

(21) Appl. No.: 10/890,959

(22) Filed: Jul. 12, 2004

(30) Foreign Application Priority Data
Aug. 1, 2003 (KR) 2003-53396

(51) Int. Cl. C23C 16/00

(52) U.S. Cl. 118/725; 427/248.1; 118/728; 118/724

(57) ABSTRACT

In one embodiment, a chemical vapor deposition (CVD) apparatus comprising a plurality of backside gas (BSG) passages that pass through a heater table that controls a temperature of a plurality of local areas on a wafer and a method of forming a thin layer using the CVD apparatus are provided. The heater table comprises a wafer supporting area divided into a plurality of local areas that correspond to the local areas of the wafer. Each of the BSG passages has a BSG outlet that supplies the BSG, heated by a heater, to the local areas. Flow controllers control the flow through each of the BSG passages, thereby controlling the temperature of local areas.

### BACKGROUND OF THE INVENTION

This application claims the priority of Korean Patent Application No. 2003-53396, filed on Aug. 1, 2003, in the Korean Intellectual Property Office, the disclosure of which is incorporated herein in its entirety by reference.

1. Field of the Invention

The present invention relates to an apparatus for manufacturing a semiconductor device and a method of forming a thin layer of a semiconductor device using the apparatus, and more particularly, to a chemical vapor deposition (CVD) apparatus and a method of forming a thin layer on a wafer using the apparatus.

2. Description of the Related Art

As a circuit line width decreases, technical limitations occur when using conventional technology when depositing wires formed of a material such as Al in the manufacturing of a semiconductor device. Therefore, a technique of filling a contact hole as a connection portion of lower conductive layer and an upper Al wires or a via hole a connection portion of a lower Al wires and an upper Al wires, using a wire material, becomes important to electrically connect the lower and the upper Al wires.

For this purpose, a variety of manufacturing technologies have been developed to better fill a recessed area, such as a contact hole, a via hole, or a trench with Al and improve electrical characteristics of the filled recess area. In a next generation memory, the aspect ratio of the contact hole is large when depositing metal wires with a circuit line width of 0.25 μm or less. Thus, a physical vapor deposition (PVD) method, such as sputtering, is not effectively employed. In order to overcome this problem, research has been conduct to produce a manufacturing process involving Al wires using a chemical vapor deposition (CVD) method, which has excellent step coverage characteristics compared to the PVD method.

However, as the aspect ratio of the recessed area filled with Al increases, step coverage of an aluminum layer is highly dependent on the kind and a thickness of the underlayer. In particular, as an aperture of a wafer becomes large and a device is scaled down, it becomes more difficult to maintain a constant thickness distribution when depositing an Al layer that is highly dependent on an underlayer. This is because the deposition rate varies according to the kind and thickness of the underlayer when forming the Al layer using the CVD method, which in turn results in an uneven thickness of the Al layer on the wafer.

### SUMMARY OF THE INVENTION

To solve the above and other problems, the present invention provides, among other things, a chemical vapor deposition (CVD) apparatus and a method of forming a thin layer which capable of improving poor thickness distribution of a material layer, for example, Al layer caused by a large aperture of a wafer, scaling down of a device and high dependence on an underlayer in a process of forming an aluminum layer by a CVD method.

According to an aspect of the present invention, there is provided a CVD apparatus comprising: a reaction chamber, in which a material layer is formed on a wafer by a CVD method; a heater table, located in the reaction chamber, having an upper surface including a wafer supporting area that is divided into a plurality of local areas and a heater that heats a backside gas (BSG); a plurality of BSG passages, disposed within the heater table, and which introduces the BSG heated by the heater to the plurality of local areas; and a flow controller which controls the amount of BSG that flows to the BSG passages for controlling the temperature of each of the local areas.

Preferably, the local areas are central supporting area that faces a central area of a wafer and an outer supporting area that faces an outer area of the wafer. Here, the plurality of BSG passages comprise a first BSG passage that supplies the BSG to the central supporting area and a second BSG passage that supplies the BSG to the outer supporting area, wherein the first and second BSG passages are arranged such that they do not communicate each other.

The flow controller comprises a first flow controller that controls the BSG flow through the first BSG passage and a second flow controller that controls the BSG flow through the second BSG passage. Each of the first and second flow controllers is a mass flow controller (MFC).

The flow controller controls the BSG flows that passes through the first and second flow controllers such that more of the BSG is supplied to the first BSG passage than the second BSG passage such that the temperature of the central area of the wafer is higher than the temperature of the outer area of the wafer. In addition, the flow controller controls the BSG that passes through the first and second flow controllers such that more of the BSG is supplied to the second BSG passage than the first BSG passage such that the temperature of the outer area of the wafer is higher than the temperature of the central area of the wafer.

The CVD apparatus according to the present invention further comprising a plurality of lift pins which pass through the heater table and support the wafer such that the wafer can be moved perpendicular to the wafer supporting area.

According to another aspect of the present invention, there is provided a method of forming a thin layer comprising: loading a wafer which has a predetermined layer, on an upper surface of a heater table, which is installed in a reaction chamber, has a wafer supporting area that is divided into a central supporting area that faces a central area of the wafer and an outer supporting area that faces facing an outer area of the wafer, and includes a heater under the upper surface that controls the temperature of the wafer supporting area; and forming an Al layer on the predetermined layer of the wafer using the CVD method while a BSG heated by the heater is independently supplied to the central and outer supporting areas in a state where the wafer supporting area is heated to a desired temperature.

Before forming the Al layer, preparing a predetermined manufacturing environment in the reaction chamber by supplying a carrier gas and the BSG to the wafer located on the area wafer supporting. If the predetermined layer is a Ti layer, in the forming of the Al layer, more of the BSG is supplied to the outer supporting area than the central supporting area. The BSG is supplied to the first and second local areas via first and second BSG passages, which are separated, respectively.

The BSG is supplied to the central supporting area through a first BSG outlet of the first BSG passage, which is located in the central supporting area, and to the outer supporting area through a second BSG outlet of the second BSG passage which located in the outer supporting area. Here, the BSG supplied through the second BSG outlet of the second BSG passage flows away from the center of the supporting area in a radial direction.

Accordingly, the BSG is independently supplied to each of the local areas of the wafer supporting area via the BSG passages which pass through the heater table, thereby independently controlling the temperature of each of the local areas of the wafer. In the method of forming the thin layer, in order to prevent an uneven thickness of the Al layer on the wafer, which may be caused by depositional characteristics, that is, the dependency on the underlayer, when forming the Al layer using the CVD method, the BSG supplied to the local areas is changed, and thus, the temperature of the wafer is subsequently changed. Therefore, the depositional characteristics and the poor thickness distribution of the Al layer on the wafer can be improved.

The above and other features and advantages of the present invention will become more apparent by describing in detail exemplary embodiments thereof with reference to the attached drawings.

### BRIEF DESCRIPTION OF THE DRAWINGS

FIG. 1 is a cross-sectional view of a chemical vapor deposition (CVD) apparatus according to a preferred embodiment of the present invention.

FIG. 2 is a top plane view of a heater table of the CVD apparatus of FIG. 1.

FIG. 3 is a flow chart illustrating a method of forming a thin layer according to a preferred embodiment of the present invention.

FIG. 4 is a graph illustrating changes in the Al deposition rate according to a thickness of a Ti underlayer, when forming an Al layer on the Ti underlayer, by a CVD method according to a conventional technology.

FIG. 5 is a graph illustrating changes in an Al deposition rate according to a thickness of a TiN underlayer, when forming an Al layer on the TiN underlayer, using conventional CVD method.

FIG. 6 is a graph illustrating a sheet resistance of an Al layer according to a process temperature in a process of manufacturing an Al layer using a CVD method.

### DETAILED DESCRIPTION OF THE INVENTION

The present invention will now be described more fully with reference to the accompanying drawings in which exemplary embodiments of the invention are shown.

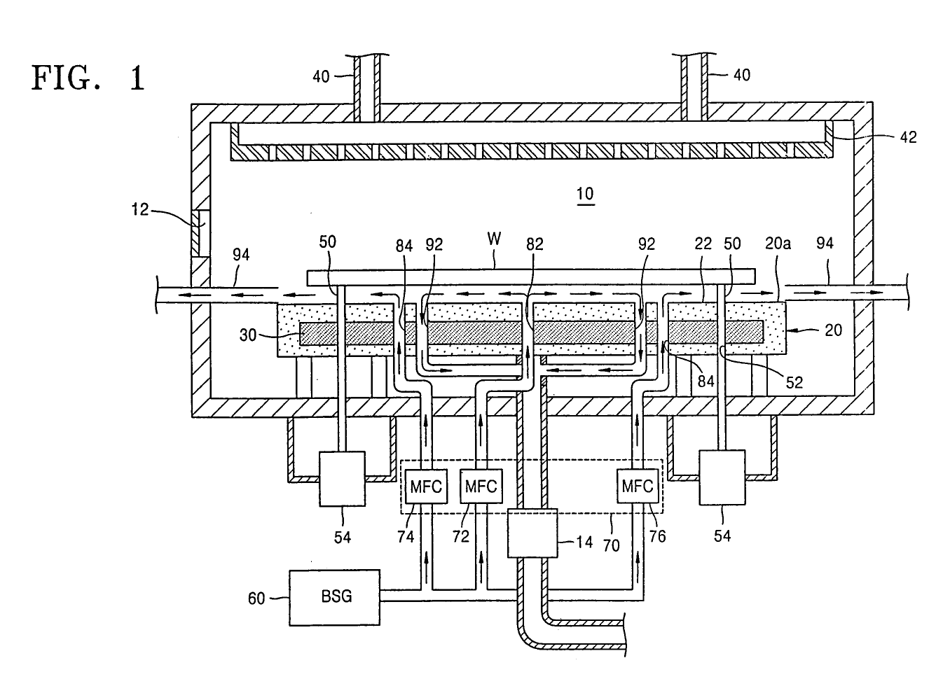

Referring to FIG. 1, a CVD apparatus comprises a reaction chamber 10 with an entrance 12 which allows a robotic arm (not shown) to enter so that a wafer W can be loaded into or unloaded from the reaction chamber 10. The reaction chamber 10 is maintained under a vacuum using a vacuum pump 14. Here, for instance, the reaction chamber 10 is an Al deposition chamber so as to form an Al layer on the wafer W. When a Ti or TiN layer is exposed on the wafer W, the CVD apparatus, which will be explained below, will operate more effectively.

A heater table 20 is located in the reaction chamber 10. The heater table 20 has an upper surface 20a that includes a wafer supporting area 22, over which the wafer W is maintained. The heater table 20 includes a heater 30 which heats the wafer supporting area 22 to a required manufacturing temperature. The heater 30 is located in the heater table 20 and may be a heating lamp, such as a resistant heating element or a halogen lamp.

The reaction chamber 10 has a shower head 42, which is formed in an upper region of the reaction chamber 10. The shower head 42 supplies a reactive gas, which is provided from the outside to the reaction chamber 10 via a supply pipe 40.

A plurality of lift pins 50, which move upwardly and downwardly, and support the wafer W. A plurality of pin holes 52, which hold the plurality of lift pins 50, pass through the heater table 20. The plurality of lift pins 50 are moved up and down by a lift mechanism 54, thereby moving the wafer W in a vertical direction when it is loaded on the wafer supporting area 22. The plurality of lift pins 50, for example, three or four lift pins, may be disposed at the edge portion of the wafer W. The wafer W, which is supported by the plurality of lift pins 50 over the wafer supporting area 22, may be heated to a desired temperature, in a manufacturing process, by the heater 30.

In addition, a plurality of backside gas (BSG) passages, specifically a first BSG passage 82 and a second BSG passage 84, are formed in the heater table 20. These passages allow a BSG to flow through the heater table 20 from a BSG source 60. The BSG, which is supplied through the plurality of BSG passages 82 and 84, is heated by the heater 30 when it passes through the plurality of BSG passages 82 and 84, and flows to the upper surface 20a of the heater table 20. Since the BSG flows to the upper surface 20a of the heater table 20, layer-forming on a backside of the wafer W is prevented, and thermal conductivity is improved.

The flow rate of the BSG is controlled by a flow controller 70, such as a mass flow controller (MFC). The flow controller 70 comprises a first mass flow controller 72 which controls the flow of the BSG to the first BSG passage 82, and second mass flow controllers 72 and 74 which control the flow of the BSG to the second BSG passage 84.

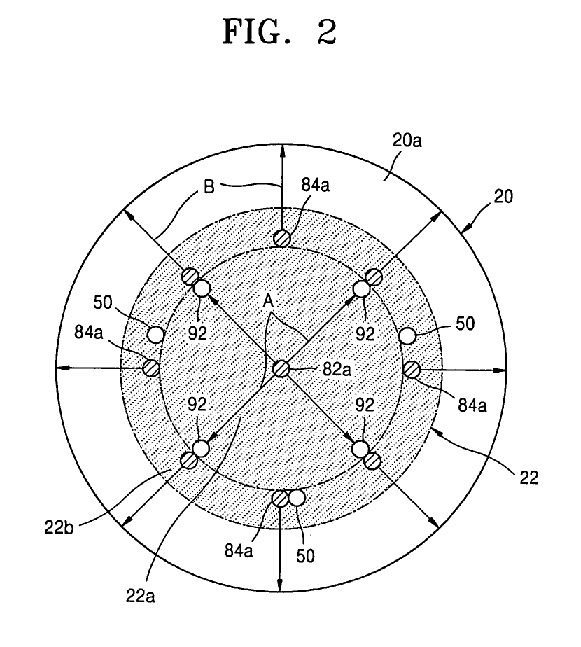

Referring to FIGS. 1 and 2, the wafer supporting area 22 comprises a plurality of supporting areas on the upper surface 20a of heater table 20. As illustrated in FIG. 2, the wafer supporting area 22 comprises a central supporting area 22a, which faces a central area of the wafer W, and an outer supporting area 22b which faces an outer area of the wafer W. However, the wafer supporting area 22 can be divided into three or more supporting areas, according to a user's necessity.

The plurality of BSG passages 82 and 84 comprise the first BSG passage 82, which supplies the BSG to the central supporting area 22a, and the second BSG passage 84, which supplies the BSG to the outer supporting area 22b. The first and second BSG passages 82 and 84 are isolated from each other so that these cannot communicate with each other. That is, the BSG supplied through the first BSG passage 82 flows to the wafer supporting area 22 via a first BSG outlet 82a which is located in the central supporting area 22a, and flows out through a first exhaust aperture 92 by flowing in a direction A in the central supporting area 22a. Furthermore, the BSG supplied through the second BSG passage 84 flows to the wafer supporting area 22 via a second BSG outlet 84a, which is located in the second local area 22b, and flows out through a second exhaust aperture 94 by flowing in direction B in the outer supporting area 22b. The second exhaust aperture 94, as shown in FIG. 1, is disposed near the wafer W, and thus, the BSG that flows through the second BSG outlet 84a of the second BSG passage 84 flows in an outward radial direction of the wafer W.

The flow of the BSG supplied through the first BSG passage 82 is controlled by the first mass flow controller 72 and the flow of the BSG supplied through the second BSG passage 84 is controlled by the second mass flow controllers 74 and 76. That is, the flow of the BSG through the first BSG passage 82 and the flow at the BSG through the second BSG passage 84 are respectively controlled by separate mass flow controllers. In FIG. 1, two second mass flow controllers 74 and 76 are illustrated, but only one second mass flow controller need be formed.

As described above, the BSG flows through the first and second BSG passages 82 and 84 are separately controlled by the mass flow controller 70, and thus, the flow of the BSG under the central and outer areas of the wafer W can be separately controlled, and the temperature of the central and outer areas of the wafer W can also be separately controlled. The BSG supplied by the BSG source 60 is heated to a desired manufacturing temperature which it flows to the upper surface 20a of the heater table 20. Therefore, when the BSG flows to the central supporting are 22a, the temperature of the central area of the wafer increases, and when the BSG gas flows to the outer supporting area 22b, the temperature of the outer area of the wafer increases. Consequently, the temperature of the wafer can be controlled locally. Thus, in order to maintain a higher temperature at the central area of the wafer W than the outer area of the wafer W, the flow controller 70 controls the BSG flow through the first mass flow controller 72, and the second mass flow controllers 74 and 76, such that more of the BSG is supplied to the first BSG passage 82 than the second BSG passage 84. In order to maintain a higher temperature at the outer area of the wafer W than the central area of the wafer W, the flow controller 70 controls the BSG flow through the first flow controller 72, and the second mass flow controllers 74 and 76, such that more of the BSG is supplied to the second BSG passage 84 than the first BSG passage 82.

As illustrated in FIG. 2, the number of the first and second BSG passages 82 and 84, that is, the number of the first BSG outlets 82a and the second BSG outlets 84a on the upper surface 20a, are one and eight, respectively; However, the number and positions of the first and second BSG passages 82 and 84 can be changed according to the size of the aperture in the wafer W.

When an Al layer is formed by a CVD method in a conventional process of manufacturing a semiconductor device, depositional characteristics, that is, uniformity of thickness and electrical characteristics, of the Al layer depend on the kind and thickness of an underlayer. According to preferred embodiments of the present invention, it is found that the depositional characteristics of the Al layer depend on whether the underlayer is a Ti or TiN layer, and the depositing speed depends on the thickness of the Ti or TiN layer. Thus, the thickness of the Al layer, which is formed on the wafer by the CVD method, depends on a position on the wafer, and thus, poor thickness distribution of the Al layer occurs. Moreover, it is found that when the Al layer is formed by the CVD method, the depositing speed increases in proportion to the depositional temperature.

A method of forming a thin layer according to a second embodiment of the present invention improves the uniformity of the thickness of the Al layer by using the CVD apparatus illustrated in FIGS. 1 and 2 and controlling the BSG supply according to the position of the wafer and the temperature of the local area on the wafer.

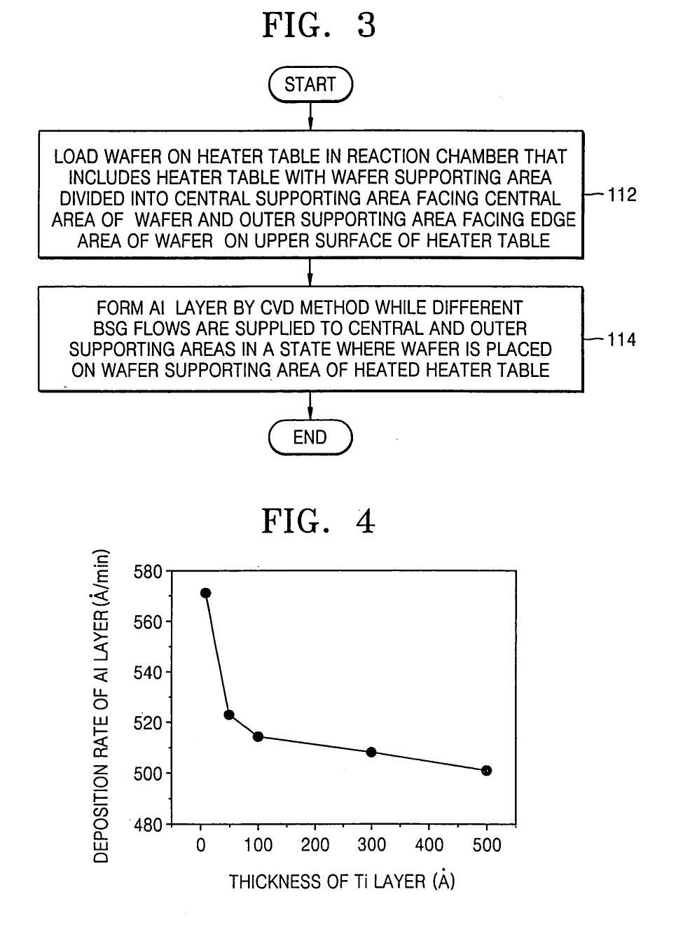

Referring to FIG. 3, the wafer W, on which a predetermined layer, for example, the Ti or TiN layer, is formed, is loaded on the heater table 20, which is located in the reaction chamber 10, in step 112.

Thereafter, a carrier gas and the BSG gas are supplied to the wafer W and produce a desired pressure in the reaction chamber 10. The carrier gas is supplied through the shower head 42 to the wafer W and the carrier gas may be an Ar gas. The BSG is supplied through the first and second BSG passages 82 and 84 by the BSG source 60 to the wafer W.

In step 114, the Al layer is formed on the predetermined layer by the CVD method under the condition that the BSG, for example the Ar gas, which is heated by the heater 30 is supplied to the wafer supporting area 22, and the wafer W is heated to a desired temperature, for instance, about 140° C., by the heater 30. The BSG flow is controlled by the mass flow controller 70 such that the BSG is supplied at independent flow rates to the central and outer supporting areas 22a and 22b. A source gas that forms the Al layer is supplied with the carrier gas through the shower head 42.

When the deposition rate in the central area of the wafer W is greater than the deposition rate in the outer area of the wafer W, in order to obtain a more uniform thickness distribution of the Al layer on the wafer W, the BSG flow is controlled by the mass flow controller 70 such that more of the BSG is supplied to the central supporting area 22a than the outer supporting area 22b. Furthermore, when the deposition rate in the outer area of the wafer is required to be greater than the deposition rate in the central area of the wafer W in order to obtain the a more uniform thickness of the Al layer on the wafer W, the BSG flow is controlled by the mass flow controller 70 such that more of the BSG is supplied to the outer supporting area 22b than the central supporting area 22a.

Referring to FIG. 4, the deposition rate of the Al layer increases as the thickness of the Ti layer decreases.

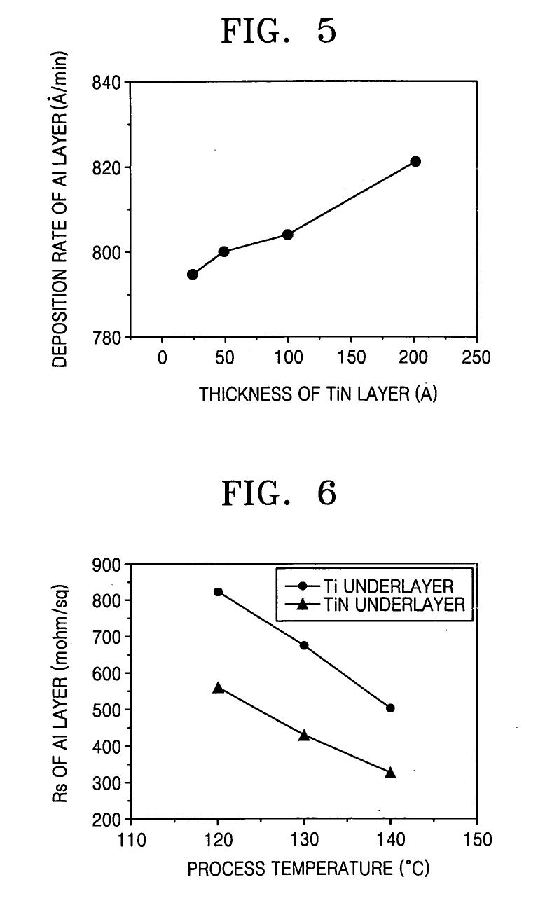

Referring to FIG. 5, the deposition rate of the Al layer increases as the thickness of the TiN underlayer increases.

Meanwhile, after forming the Al layers on the Ti and TiN underlayers on the wafer W using the CVD method, the respective thickness of the Al layers obtained from the sheet resistance Rs map can be compared. When the Al layer is formed on the Ti underlayer, the sheet resistance Rs of the Al layer is lower in the outer area of the wafer W than the central area of the wafer W. When the Al layer is formed on the TiN underlayer, the sheet resistance Rs of the Al layer is lower in the central area of the wafer W than the outer area of the wafer W. That is, the Al layer is formed thicker in the outer area than the central area in the former case, while the Al layer is formed thicker in the central area than the inner area in the latter case.

This is because there are variations in the Ti and TiN underlayers, and the thicknesses of the Ti and TiN underlayers decrease from the central area to the outer area of the wafer, based on the results depicted in FIGS. 4 and 5.

The thickness distribution of the Ti underlayer and the Al layer which is formed on the Ti underlayer, and the thickness distribution of the TiN underlayer and Al layer which is formed on the TiN underlayer, are respectively determined using the data graphically represented in FIGS. 4 and 5. According to the above data, when the Al layer is formed on the Ti layer in FIG. 4, the thickness distribution of the Ti underlayer and the Al layer are ±25 Å and ±25 Å, respectively. When the Al layer is formed on the TiN underlayer in FIG. 5, the thickness distribution of the TiN underlayer and the Al layer are ±25 Å and ±50 Å, respectively. Based on this result, it can be concluded that the thickness of the underlayer on the wafer influences the thickness of the Al layer which is formed on the underlayer by the CVD method.

Therefore, the thickness of the Al layer deposited by the CVD method is largely influenced by the thickness of the underlayer. More specifically, in the case of the Ti underlayer, the Al layer is thicker in the outer area of the wafer W than the central area of the wafer W. On the contrary, in the case of the TiN underlayer, the Al layer is thicker in the central area of the wafer W than the outer area of the wafer W.

Referring to FIG. 6, regardless of the nature of the underlayer, as the temperature in the manufacturing process increases, the sheet resistance Rs of the Al layer decreases. The decrease in the sheet resistance Rs indicates the increase in the thickness of the Al layer, and thus, as the temperature of the manufacturing process increases, the thickness of the deposited Al layer also increases.

Therefore, when the Al layer is formed on the Ti underlayer using the CVD method, the thickness uniformity of the Al layer on the wafer can be maximized if the temperature of the central area of the wafer W is higher than the temperature of the outer area of the wafer W when forming the Al layer. Furthermore, when the Al layer is formed on the TiN underlayer using the CVD method, the thickness uniformity of the Al layer on the wafer can be maximized if the temperature of outer area of the wafer W is higher than the temperature of the central area of the wafer W when forming the Al layer. According to an estimated thickness of the Al layer determined from the sheet resistance Rs based on the data graphically represented in FIG. 6, about 5 degrees C. should separate the temperature of the central and outer areas of the wafer W in order to overcome a 50 Å difference in thickness between the central and outer areas of the wafer W.

The CVD apparatus according to the first embodiment of the present invention is able to effectively, independently control the central and outer areas of the wafer. As mentioned above, the CVD apparatus according to the first embodiment of the present invention independently supplies the BSG to the central area and to the outer area of the wafer W and independently controls the BSG flow to these areas. Thus, the temperatures can be independently controlled in the central and outer of the wafer W these areas by controlling the BSG supplied to these areas, thereby controlling the thickness distribution of the Al layer formed by CVD. That is, when more of the BSG is supplied to the central area of the wafer than the outer area of the wafer, the temperature of the central area of the wafer becomes higher than the outer area of the wafer. Thus, the uniformity of the thickness of the Al layer is improved when forming the Al layer on the Ti underlayer. Furthermore, when more of the BSG is supplied to the outer area of the wafer W than the central area of the wafer W, the temperature of the outer area of the wafer W becomes higher than the temperature of the central area of the wafer W. Thus, the uniformity in thickness of the Al layer is improved when forming the Al layer on the TiN underlayer.

Moreover, the CVD apparatus according to preferred embodiments of the present invention comprises a plurality of the BSG passages which pass through the heater table. The different BSG flows can be supplied to the plurality of local areas through the plurality of the BSG passages. Therefore, the temperature of each of the local areas can be independently controlled. Furthermore, the deposition rate can be changed by independently controlling the BSG flow corresponding to each of the local areas of the wafer when forming the Al layer using the CVD apparatus. Thus, it is possible to improve the thickness distribution of the Al layer on the wafer which may be caused by the large diameter of the wafer, the scaling of the device, the dependency on the underlayer, etc., using the CVD apparatus of the present invention.

In the method of forming the thin layer according to the preferred embodiments of the present invention, the Al layer is formed on the underlayer using the CVD method by independently supplying the BSG, which is heated by the heater, to the respective local areas of the wafer when the wafer is disposed on the wafer supplying area. The temperature dependency based on the depositing speed of the Al layer is used to prevent the uneven thickness of the Al layer on the wafer. This may be caused by the depositional characteristics, that is, the dependency on the underlayer when forming the Al layer by the CVD method. In this case, the BSG flow is controlled separately for each of the local areas of the wafer, and thus, the temperature of the wafer can be locally changed according to a predetermined product configuration. In this way, the depositional characteristics and the poor thickness distribution of the Al layer on the wafer can be improved.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A chemical vapor deposition (CVD) apparatus comprising:
a reaction chamber for forming a material layer on a wafer by a CVD method;
a heater table, located in the reaction chamber, having an upper surface including a wafer supporting area that is divided into a plurality of local areas and a heater that heats a backside gas (BSG);
a plurality of BSG passages, disposed within the heater table, which introduce BSG heated by the heater to the plurality of local areas; and
a flow controller system which regulates the flow of BSG to the BSG passages for controlling the temperature in each of the local areas.

2. The CVD apparatus of claim 1, wherein the local areas comprise a central supporting area that faces a central area of a wafer and an outer supporting area that faces an outer area of the wafer.

3. The CVD apparatus of claim 2, wherein the plurality of BSG passages comprise a first BSG passage that supplies the BSG to the central supporting area and a second BSG passage that supplies the BSG to the outer supporting area, wherein the first and second BSG passages are arranged such that they are not in communication with each other.

4. The CVD apparatus of claim 3, wherein the flow controller system comprises a first flow controller that controls the BSG flow through the first BSG passage and a second flow controller that controls the BSG flow through the second BSG passage.

5. The CVD apparatus of claim 4, wherein each of the first and second flow controllers comprise a mass flow controller.

6. The CVD apparatus of claim 4, wherein the flow controller system regulates the BSG flow through the first and second flow controllers so that more BSG is supplied to the first BSG passage than the second BSG passage wherein the temperature of the central area of the wafer is higher than the temperature of the outer area of the wafer.

7. The CVD apparatus of claim 4, wherein the flow controller system regulates the BSG flow through the first and second flow controllers so that more BSG is supplied to the second BSG passage than the first BSG passage wherein the temperature of the outer area of the wafer is higher than the temperature of the central area of the wafer.

8. The CVD apparatus of claim 1, wherein the material layer formed on the wafer by the CVD process comprises aluminum.

9. The CVD apparatus of claim 8, wherein a Ti or TiN underlayer is formed on the wafer, and the material layer produced by the CVD process is formed on the Ti or TiN underlayer.

10. The CVD apparatus of claim 1, further comprising a plurality of lift pins which pass through the heater table and support the wafer such that the wafer can be moved perpendicularly to the wafer supporting area.

11. A method of forming a thin layer comprising:
providing a reaction chamber having a heater table therein, the heater table including an upper surface defining a wafer supporting area that is divided into a central supporting area that faces a central area of the wafer and an outer supporting area that faces an outer area of the wafer, and a heater that controls the temperature in the wafer supporting area;
loading a wafer having an underlayer formed thereon onto the upper surface of the heater table, and
forming a material layer on the underlayer of the wafer using a CVD method, while supplying a BSG heated by the heater to the central supporting area and the outer supporting area, wherein the wafer supporting area is heated to a predetermined temperature.

12. The method of claim 11, further comprising, before forming the material layer, supplying a carrier gas and the BSG to the wafer located on the wafer supporting area.

13. The method of claim 11, wherein during the formation of the material layer, supplying more BSG to the central supporting area than to the outer supporting area.

14. The method of claim 13, wherein the underlayer is a Ti layer and the material layer is Al.

15. The method of claim 11, wherein during the formation of the material layer, supplying more BSG to the outer supporting area than to the central supporting area.

16. The method of claim 15, wherein the underlayer is a TiN layer and the material layer is Al.

17. The method of claim 11, wherein during the formation of the Al layer, supplying the BSG to the first local area and second local area through first BSG passage and second BSG passage, respectively.

18. The method of claim 17, which further includes supplying BSG to the central supporting area through a first BSG outlet of the first BSG passage located in the central supporting area, and to the outer supporting area through a second BSG outlet of the second BSG passage located in the outer supporting area.

19. The method of claim 18, which further includes supplying the BSG through the second BSG outlet of the second BSG passage flows in an outwardly radial direction away from the center of the supporting area.

20. The method of claim 11, wherein the BSG is an Ar gas.
